(19) United States
(12) Patent Application Publication
(10) Pub. No.: US 2011/0227661 A1
(43) Pub. Date: Sep. 22, 2011

(54) GLASS SUBSTRATE BONDING METHOD, GLASS ASSEMBLY, PACKAGE MANUFACTURING METHOD, PACKAGE, PIEZOELECTRIC VIBRATOR, OSCILLATOR, ELECTRONIC DEVICE, AND RADIO-CONTROLLED TIMEPIECE

(76) Inventors: Masashi NUMATA, Chiba-shi (JP); Kiyoshi ARATAKE, Chiba-shi (JP)

(21) Appl. No.: 13/050,264

(22) Filed: Mar. 17, 2011

(30) Foreign Application Priority Data
Mar. 19, 2010 (JP) 2010-065127

(51) Int. Cl. H01L 41/053; H03B 5/32; H01L 41/22

(52) U.S. Cl. 331/158; 310/344; 29/25.35

(57) ABSTRACT

Provided are a glass substrate bonding method capable of securely anodically bonding a bonding material and a glass substrate even when Si having a large resistance value is used as a material for the bonding material, a glass assembly obtained by the glass substrate bonding method, a package manufacturing method, a package, a piezoelectric vibrator, and an oscillator, an electronic device, and a radio-controlled timepiece having the piezoelectric vibrator. A glass substrate bonding method includes an anodic bonding step of anodically bonding a bonding material fixed to an inner surface of a lid substrate wafer to a base substrate wafer. The bonding material is formed of an ITO film and a Si film which are sequentially formed on the inner surface of the lid substrate wafer.

### RELATED APPLICATIONS

This application claims priority under 35 U.S.C. §119 to Japanese Patent Application No. 2010-065127 filed on Mar. 19, 2010, the entire content of which is hereby incorporated by reference.

### BACKGROUND OF THE INVENTION

1. Field of the Invention

The present invention relates to a glass substrate bonding method, a glass assembly, a package manufacturing method, a package, a piezoelectric vibrator, and an oscillator, an electronic device, and a radio-controlled timepiece each having the piezoelectric vibrator.

2. Description of the Related Art

Recently, a piezoelectric vibrator (package) utilizing quartz crystal or the like has been used in cellular phones and portable information terminals as the time source, the timing source of a control signal, a reference signal source, and the like. Although there are various piezoelectric vibrators of this type, a surface mounted device (SMD)-type piezoelectric vibrator is known as one example thereof. The piezoelectric vibrator of this type includes, for example, a base substrate and a lid substrate which are bonded to each other, a cavity formed between the two substrates, and a piezoelectric vibrating reed (electronic component) accommodated in a state of being airtightly sealed in the cavity.

As a method of directly bonding the base substrate and the lid substrate which are made of a glass material, anodic bonding has been proposed. For example, JP-A-2001-72433 and JP-A-7-183181 disclose an anodic bonding method that involves fixing a bonding material to an inner surface of one substrate, and then connecting a probe to the bonding material to be used as an anode, disposing a cathode on an outer surface of the other substrate, and applying a voltage between the bonding material and the cathode to bond the bonding material to an inner surface of the other substrate. As a material for the bonding material, Al having a relatively low resistance value is used.

However, there is a problem in that when the bonding material used for the anodic bonding is exposed to the outside of the bonded package, the bonding material made of Al will be corroded, and airtightness of the package will be degraded. Therefore, in order to prevent corrosion of Al, it is necessary to perform processing such as coating the package after the anodic bonding.

Therefore, in recent years, the use of Si has been investigated as material for the bonding material due to its superior resistance to corrosion.

However, since the Si film has a large sheet resistance, when the thin bonding material is made of Si, the resistance value will increase. For this reason, when the probe is connected to the bonding material during the anodic bonding, a voltage drop will increase in proportion to the distance from a probe connection point. As a result, there is a problem in that the potential of the bonding material may be uneven, and anodic bonding is not achieved at positions distant from the probe connection point although anodic bonding is achieved near the probe connection point. In order to achieve the anodic bonding at positions distant from the probe connection point, it is necessary to perform anodic bonding by applying a high voltage, which may however increase the amount of energy consumption. In contrast, although forming a thick Si film to decrease the sheet resistance can be considered, in this case, the deposition time of the Si film increases, which may result in the decrease of manufacturing efficiency.

Furthermore, although the Si film can be deposited by a CVD method, impurities (boron contained in a target) are scattered during the deposition, and the content of impurities in the deposited Si film decreases. As a result, the sheet resistance of the Si film increases further, and in some cases, it is difficult to apply a voltage directly to the Si film. Moreover, when the Si film is deposited using the CVD method, since special gases such as monosilane gas are used, the gases are difficult to handle and cannot be introduced.

### SUMMARY OF THE INVENTION

The present invention has been made in view of the above problems, and an object of the present invention is to provide a glass substrate bonding method capable of securely anodically bonding a bonding material and a glass substrate even when Si having a large resistance value is used as a material for the bonding material, a glass assembly obtained by the glass substrate bonding method, a package manufacturing method, a package, a piezoelectric vibrator, and an oscillator, an electronic device, and a radio-controlled timepiece having the piezoelectric vibrator.

In order to solve the problems, the invention provides the following means.

According to an aspect of the present invention, there is provided a glass substrate bonding method for bonding a first glass substrate and a second glass substrate, the method including an anodic bonding step of anodically bonding a bonding material fixed to an inner surface of the first glass substrate to the second glass substrate, in which the bonding material is formed of an ITO film and a Si film which are sequentially formed on the inner surface of the first glass substrate.

According to this configuration, by forming an ITO film which is a conductive film on the inner surface of the first glass substrate as a base layer of a Si film having a large sheet resistance, it is possible to decrease the sheet resistance of the bonding material compared to the case of forming the bonding material only of the Si film. In this way, even when the thickness of the Si film is decreased, it is possible to apply a uniform voltage to the entire surface of the bonding material. Moreover, since the thickness of the Si film can be decreased, it is possible to decrease the deposition time of the Si film and to improve the manufacturing efficiency. Therefore, even when a Si film having a large sheet resistance is used as the material for the bonding material, the two glass substrates can be tightly anodically bonded over the entire region of the bonding surface. In this case, since the anodic bonding can be achieved with a relatively low voltage, it is possible to decrease energy consumption.

Furthermore, since the ITO film and the Si film have resistance to corrosion, even when the bonding material used for the anodic bonding is exposed to the outside, the bonding material is not corroded. Therefore, it is not necessary to perform coating processing after the anodic bonding unlike the case of using Al for the bonding material, for example. In this way, it is possible to improve the manufacturing efficiency.

In the glass substrate bonding method, it is preferable that in the anodic bonding step, a positive electrode is connected to the ITO film and a negative electrode is disposed on an outer surface of the second glass substrate, and a voltage is applied between the two electrodes.

As a method for anodically bonding the first glass substrate and the second glass substrate, there is known a method (a so-called counter electrode method) in which an auxiliary bonding material serving as a positive electrode is disposed on the outer surface of the first glass substrate and a negative electrode is disposed on the outer surface of the second glass substrate. When the counter electrode method is used, an auxiliary bonding material which can be anodically bonded to the first glass substrate is used, and the bonding material and the second glass substrate are bonded in conjunction with the anodic bonding reaction between the auxiliary bonding material and the first glass substrate. Therefore, in the counter electrode method, it is necessary to perform a step of removing the auxiliary bonding material bonded to the first glass substrate after the bonding step.

In contrast, according to the configuration of the present invention, a method (a so-called direct electrode method) in which the positive electrode is connected to the ITO film, the negative electrode is disposed on the outer surface of the second glass substrate, and a voltage is directly applied to the ITO film is used. Therefore, it is possible to decrease the number of manufacturing steps and to improve the manufacturing efficiency compared to the counter electrode method described above.

In the glass substrate bonding method, it is preferable that the Si film is deposited by a sputtering method.

According to this configuration, since the deposition can be performed easily without using special gases such as monosilane gas, it is possible to improve the manufacturing efficiency as compared to the case of depositing the Si film by the CVD method.

According to another aspect of the present invention, there is provided a glass assembly in which a bonding material fixed to an inner surface of a first glass substrate is anodically bonded to a second glass substrate, in which the bonding material is a laminated material in which an ITO film is formed on an inner surface of the first glass substrate and a Si film is formed on the ITO film.

According to this configuration, by forming an ITO film which is a conductive film on the inner surface of the first glass substrate as a base layer of a Si film having a large sheet resistance, it is possible to decrease the sheet resistance of the bonding material compared to the case of forming the bonding material only of the Si film. In this way, it is possible to form a glass assembly in which the entire regions of the bonding surfaces of the two glass substrates are tightly anodically bonded as described above. In this case, since the thickness of the Si film can be decreased, it is possible to decrease the thickness of the glass assembly.

Furthermore, since the ITO film and the Si film have resistance to corrosion, even when the bonding material used for the anodic bonding is exposed to the outside, the bonding material is not corroded. Therefore, it is not necessary to perform coating processing after the anodic bonding unlike the case of using Al for the bonding material, for example. In this way, it is possible to improve the manufacturing efficiency.

According to a further aspect of the present invention, there is provided a method for manufacturing a package capable of sealing an electronic component between a first glass substrate and a second glass substrate, the method including: an anodic bonding step of anodically bonding the first glass substrate and the second glass substrate using the glass substrate bonding method according to the above aspect of the present invention; and a fragmentation step of fragmenting the glass assembly to form a plurality of packages, in which in the anodic bonding step, a positive electrode is connected to the ITO film at an end of the first glass substrate, a negative electrode is disposed on an outer surface of the second glass substrate, and a voltage is applied between the two electrodes.

According to this configuration, since the glass substrates are bonded using the glass substrate bonding method according to the above aspect of the present invention, even when a positive electrode is connected to the end of the first glass substrate, it is possible to apply a uniform voltage to the entire surface of the bonding material. That is, it is possible to easily form a glass assembly in which the entire regions of the bonding surfaces of the two glass substrates are tightly anodically bonded without the necessity of connecting the positive electrode at plurality of positions and considering the connection positions of the positive electrode in order to apply a uniform voltage to the entire surface of the bonding material. Moreover, since the package of the present invention is obtained by fragmenting the glass assembly manufactured as described above, it is possible to secure the airtightness of the cavities of the respective packages.

Furthermore, since the ITO film and the Si film have resistance to corrosion as described above, even when the bonding material used for the anodic bonding is exposed to the outside, the bonding material is not corroded. Therefore, it is possible to prevent the decrease of the airtightness of the package while improving the manufacturing efficiency.

According to a still further aspect of the present invention, there is provided a package which is manufactured by the package manufacturing method according to the above aspect of the present invention.

According to this configuration, since the package is manufactured by the package manufacturing method according to the above aspect of the present invention, it is possible to provide a package having excellent airtightness.

According to a still further aspect of the present invention, there is provided a piezoelectric vibrator in which a piezoelectric vibrating reed is airtightly sealed in the cavity of the package according to the above aspect of the present invention.

According to this configuration, since the piezoelectric vibrator includes the package having excellent airtightness, it is possible to improve the vacuum sealing reliability of the piezoelectric vibrating reed. In this way, since a series resonance resistance value (R1) of the piezoelectric vibrator is maintained at a low state, it is possible to vibrate the piezoelectric vibrating reed with a low power. Thus, it is possible to manufacture a piezoelectric vibrator having excellent energy efficiency.

According to a still further aspect of the present invention, there is provided an oscillator in which the piezoelectric vibrator according to the above aspect of the present invention is electrically connected to an integrated circuit as an oscillating piece.

According to a still further aspect of the present invention, there is provided an electronic device in which the piezoelectric vibrator according to the above aspect of the present invention is electrically connected to a clock section.

According to a still further aspect of the present invention, there is provided a radio-controlled timepiece in which the piezoelectric vibrator according to the above aspect of the present invention is electrically connected to a filter section.

In the oscillator, electronic device, and radio-controlled timepiece according to the above aspects of the present invention, since they have the above-described piezoelectric vibrator having excellent energy efficiency, it is possible to provide products having excellent energy efficiency similarly to the piezoelectric vibrator.

According to the glass substrate bonding method and the glass assembly according to the above aspects of the present invention, it is possible to apply a uniform voltage to the entire surface of the bonding material even when the thickness of the Si film is decreased. Moreover, since the thickness of the Si film can be decreased, it is possible to decrease the deposition time of the Si film and to improve the manufacturing efficiency. Therefore, even when a Si film having a large sheet resistance is used as the material for the bonding material, the two glass substrates can be tightly anodically bonded over the entire region of the bonding surface.

According to the package manufacturing method and the package according to the above aspects of the present invention, since the glass substrates are bonded using the glass substrate bonding method according to the above aspect of the present invention, it is possible to easily form a glass assembly in which the entire regions of the bonding surfaces of the two glass substrates are tightly anodically bonded without the necessity of connecting the positive electrode at plurality of positions and considering the connection positions of the positive electrode in order to apply a uniform voltage to the entire surface of the bonding material. Moreover, the package of the present invention is obtained by fragmenting the glass assembly manufactured as described above, it is possible to secure the airtightness of the cavities of the respective packages.

According to the piezoelectric vibrator according to the above aspect of the present invention, it is possible to provide a piezoelectric vibrator in which the airtightness of the cavity is secured and which has excellent vibration characteristics and high reliability.

In the oscillator, electronic device, and radio-controlled timepiece according to the above aspects of the present invention, since they have the above-described piezoelectric vibrator having excellent energy efficiency, it is possible to provide products having excellent energy efficiency similarly to the piezoelectric vibrator.

### BRIEF DESCRIPTION OF THE DRAWINGS

FIG. 1 is a perspective view showing an external appearance of a piezoelectric vibrator according to an embodiment of the present invention.

FIG. 2 is a top view showing a state where a lid substrate of the piezoelectric vibrator is removed.

FIG. 3 is a cross-sectional view of the piezoelectric vibrator taken along the line A-A in FIG. 2.

FIG. 4 is an exploded perspective view of the piezoelectric vibrator shown in FIG. 1.

FIG. 5 is a top view of a piezoelectric vibrating reed.

FIG. 6 is a bottom view of the piezoelectric vibrating reed.

FIG. 7 is a cross-sectional view taken along the line B-B in FIG. 5.

FIG. 8 is a flowchart of the manufacturing method of a piezoelectric vibrator according to an embodiment of the present invention.

FIG. 9 is an exploded perspective view of a wafer assembly.

FIG. 10 illustrates a bonding material forming step and is a cross-sectional view of a lid substrate wafer.

FIG. 11 illustrates a bonding material forming step and is a cross-sectional view of a lid substrate wafer.

FIG. 12 illustrates a bonding step and is a partially enlarged cross-sectional view taken along the line C-C in FIG. 9.

FIG. 13 is a view showing the configuration of an oscillator according to an embodiment of the present invention.

FIG. 14 is a view showing the configuration of an electronic device according to an embodiment of the present invention.

FIG. 15 is a view showing the configuration of a radio-controlled timepiece according to an embodiment of the present invention.

### DETAILED DESCRIPTION OF THE PREFERRED EMBODIMENTS

Hereinafter, an embodiment of the present invention will be described with reference to the drawings.

### Piezoelectric Vibrator

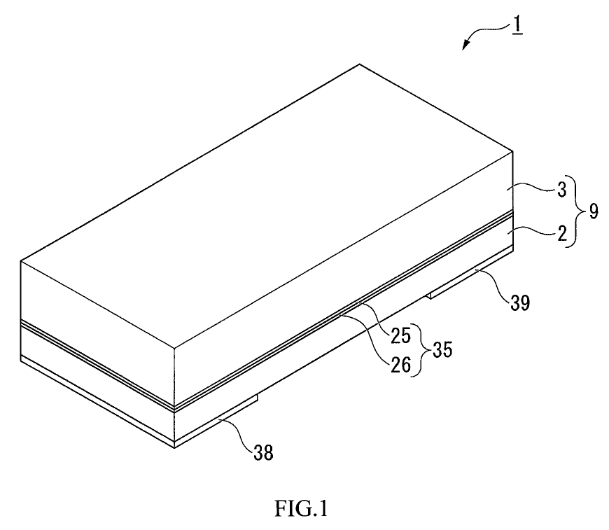

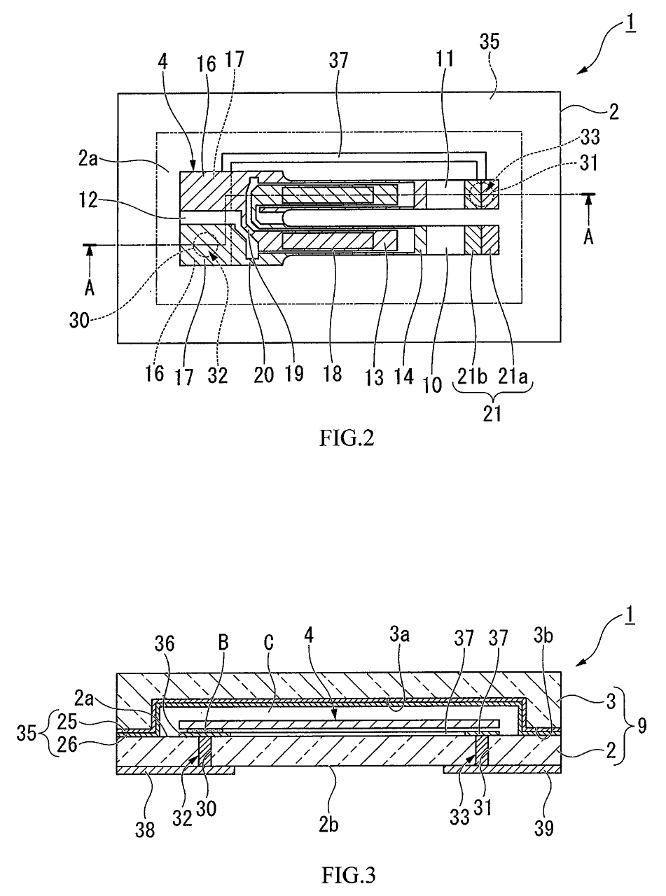

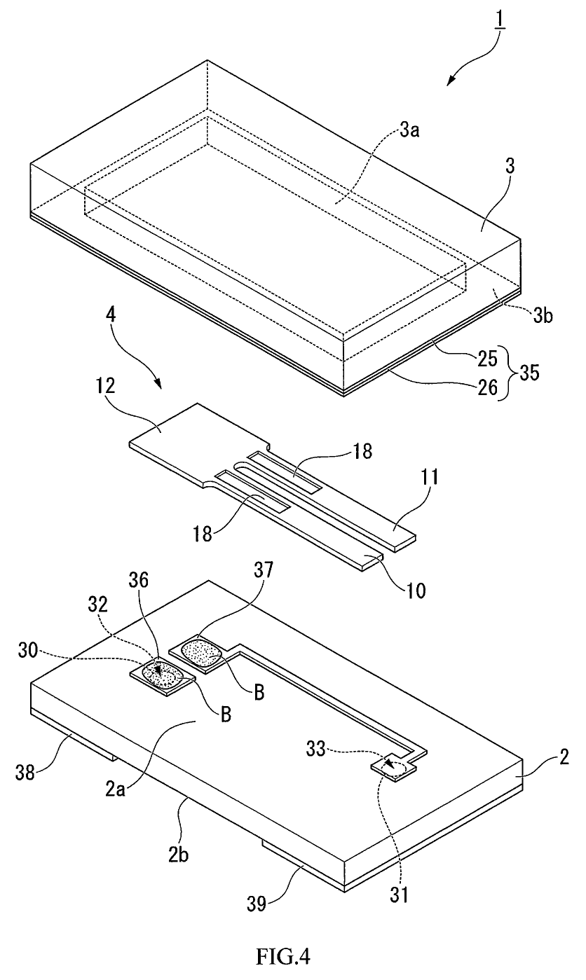

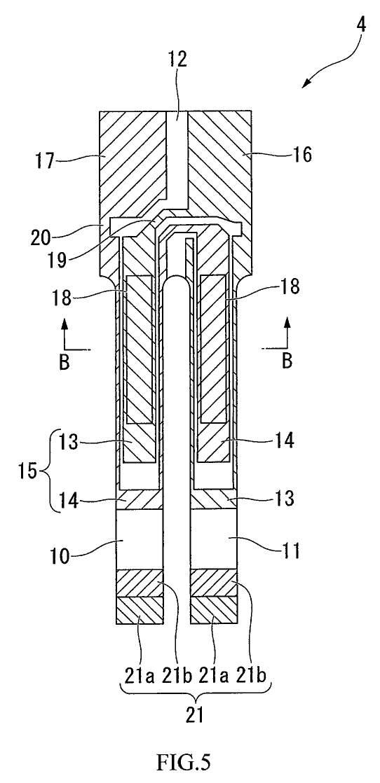

First, a piezoelectric vibrator according to the embodiment of the present invention will be described with reference to the drawings. FIG. 1 is a perspective view showing an external appearance of a piezoelectric vibrator according to an embodiment of the present invention. FIG. 2 is a top view showing a state where a lid substrate of the piezoelectric vibrator is removed. FIG. 3 is a cross-sectional view of the piezoelectric vibrator taken along the line A-A in FIG. 2. FIG. 4 is an exploded perspective view of the piezoelectric vibrator shown in FIG. 1. In FIG. 4, for better understanding of the drawings, the illustrations of excitation electrode 15, extraction electrodes 19 and 20, mount electrodes 16 and 17, and weight metal film 21 of a piezoelectric vibrating reed 4 described later are omitted.

As shown in FIGS. 1 to 4, a piezoelectric vibrator 1 according to the present embodiment is a surface mounted device-type piezoelectric vibrator 1 which includes a package 9, in which a base substrate 2 and a lid substrate 3 are anodically bonded by a bonding material 35, and a piezoelectric vibrating reed 4 which is accommodated in a cavity C of the package 9.

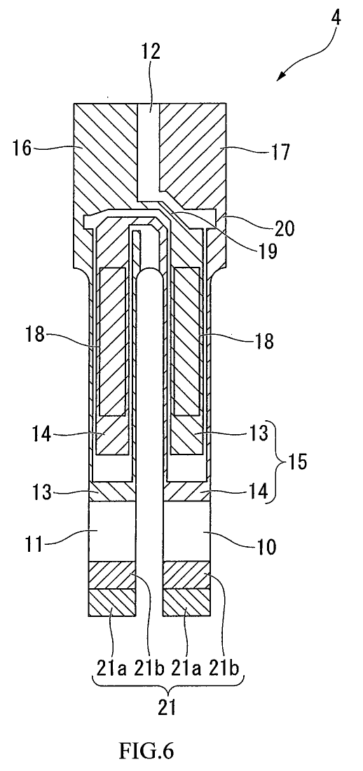

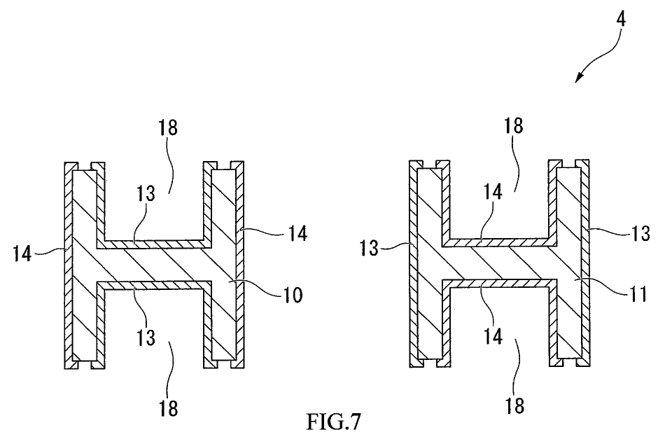

FIG. 5 is a top view of a piezoelectric vibrating reed; FIG. 6 is a bottom view of the piezoelectric vibrating reed; and FIG. 7 is a cross-sectional view taken along the line B-B in FIG. 5.

As shown in FIGS. 5 to 7, the piezoelectric vibrating reed 4 is a turning-fork type vibrating reed which is made of a piezoelectric material such as quartz crystal, lithium tantalate, or lithium niobate and is configured to vibrate when a predetermined voltage is applied thereto. The piezoelectric vibrating reed 4 includes a pair of vibrating arms 10 and 11 disposed in parallel to each other, a base portion 12 to which the base end sides of the pair of vibrating arms 10 and 11 are integrally fixed, and groove portions 18 which are formed on both principal surfaces of the pair of vibrating arms 10 and 11. The groove portions 18 are formed so as to extend from the base end sides of the vibrating arms 10 and 11 along the longitudinal direction of the vibrating arms 10 and 11 up to approximately the middle portions thereof.

In addition, the piezoelectric vibrating reed 4 of the present embodiment includes: an excitation electrode 15 which is formed on the outer surfaces of the base ends of the pair of vibrating arms 10 and 11 so as to allow the pair of vibrating arms 10 and 11 to vibrate and includes a first excitation electrode 13 and a second excitation electrode 14; and mount electrodes 16 and 17 which are electrically connected to the first excitation electrode 13 and the second excitation electrode 14, respectively. The excitation electrode 15, mount electrodes 16 and 17, and extraction electrodes 19 and 20 are formed by a coating of a conductive film of chromium (Cr), nickel (Ni), aluminum (Al), and titanium (Ti), for example.

The excitation electrode 15 is an electrode that allows the pair of vibrating arms 10 and 11 to vibrate at a predetermined resonance frequency in a direction moving closer to or away from each other. The first excitation electrode 13 and second excitation electrode 14 that constitute the excitation electrode 15 are patterned and formed on the outer surfaces of the pair of vibrating arms 10 and 11 in an electrically isolated state. Specifically, the first excitation electrode 13 is mainly formed on the groove portion 18 of one vibrating arm 10 and both side surfaces of the other vibrating arm 11. On the other hand, the second excitation electrode 14 is mainly formed on both side surfaces of one vibrating arm 10 and the groove portion 18 of the other vibrating arm 11. Moreover, the first excitation electrode 13 and the second excitation electrode 14 are electrically connected to the mount electrodes 16 and 17 via the extraction electrodes 19 and 20, respectively, on both principal surfaces of the base portion 12.

Furthermore, the tip ends of the pair of the vibrating arms 10 and 11 are coated with a weight metal film 21 for adjustment of the vibration states (tuning the frequency) of the pair of the vibrating arms 10 and 11 in a manner such as to vibrate within a predetermined frequency range. The weight metal film 21 is divided into a rough tuning film 21a used for tuning the frequency roughly and a fine tuning film 21b used for tuning the frequency finely.

As shown in FIGS. 1, 3, and 4, the lid substrate 3 is a substrate that can be anodically bonded and that is made of a glass material, for example, soda-lime glass, and is formed in a substrate-like form. On a bonding surface side of the lid substrate 3 to be bonded to the base substrate 2, a recess portion 3a for a cavity C is formed in which the piezoelectric vibrating reed 4 is accommodated.

A bonding material 35 for anodic bonding is formed on approximately the entire surface (inner surface) on the bonding surface side of the lid substrate 3 to be bonded to the base substrate 2. That is to say, the bonding material 35 is formed in a frame region at the periphery of the recess portion 3a in addition to the entire inner surface of the recess portion 3a (these regions will be collectively referred to as an inner surface 3b of the lid substrate 3). In the present embodiment, the bonding material 35 is made up of an ITO (Indium Tin Oxide) film 25 formed on the inner surface 3b of the lid substrate 3 and a Si film 26 formed on the ITO film 25. The ITO film 25 is a conductive film having resistance to corrosion and is a compound in which 5 to 10 wt % of tin oxide (SnO₂) is added to indium oxide (In₂O₃). In the present embodiment, the ITO film 25 is formed to a thickness of about 1000 Å to 1500 Å, for example. On the other hand, the Si film 26 is formed on the same region as the formation region of the ITO film 25 so as to cover the ITO film 25 and is formed to a thickness of about 1500 Å, for example. As will be described later, the Si film 26 of the bonding material 35 and the base substrate 2 are anodically bonded, whereby the cavity C is vacuum-sealed.

The base substrate 2 is a substrate that is made of a glass material, for example, soda-lime glass, and is formed in an approximately substrate-like form having the same outer shape as the lid substrate 3 as shown in FIGS. 1 to 4.

On an inner surface 2a side (a bonding surface side to be bonded to the lid substrate 3) of the base substrate 2, a pair of lead-out electrodes 36 and 37 is patterned as shown in FIGS. 1 to 4. The lead-out electrodes 36 and 37 are formed by a laminated structure of a lower Cr film and an upper Au film, for example.

As shown in FIGS. 3 and 4, the mount electrodes 16 and 17 of the above-described piezoelectric vibrating reed 4 are bump-bonded to the surfaces of the lead-out electrodes 36 and 37 via bumps B made of gold or the like. The piezoelectric vibrating reed 4 is bonded in a state where the vibrating arms 10 and 11 are floated from the inner surface 2a of the base substrate 2.

In addition, a pair of penetration electrodes 32 and 33 is formed on the base substrate 2 so as to penetrate through the base substrate 2. The penetration electrodes 32 and 33 are formed of a metallic material having conductive properties such as stainless steel, Ag, or Al. One penetration electrode 32 is formed right below one lead-out electrode 36. The other penetration electrode 33 is formed in the vicinity of a tip end of the vibrating arm 11 and is connected to the other lead-out electrode 37 via a lead-out wiring.

In addition, a pair of outer electrodes 38 and 39 is formed on an outer surface 2b of the base substrate 2 as shown in FIGS. 1, 3, and 4. The pair of outer electrodes 38 and 39 is formed at both ends in the longitudinal direction of the base substrate 2 and is electrically connected to the pair of penetration electrodes 32 and 33.

When the piezoelectric vibrator 1 configured in the way is operated, a predetermined driving voltage is applied between the outer electrodes 38 and 39 formed on the base substrate 2. By doing so, current flows from the one outer electrode 38 to the first excitation electrode 13 of the piezoelectric vibrating reed 4 through the one penetration electrode 32 and the one lead-out electrode 36. Moreover, current flows from the other outer electrode 39 to the second excitation electrode 14 of the piezoelectric vibrating reed 4 through the other penetration electrode 33 and the other lead-out electrode 37. In this way, current can be made to flow to the excitation electrode 15 including the first and second excitation electrodes 13 and 14 of the piezoelectric vibrating reed 4, and the pair of vibrating arms 10 and 11 is allowed to vibrate at a predetermined frequency in a direction moving closer to or away from each other. The vibration of the pair of vibrating arms 10 and 11 can be used as the time source, the timing source of a control signal, the reference signal source, and the like.

### Piezoelectric Vibrator Manufacturing Method

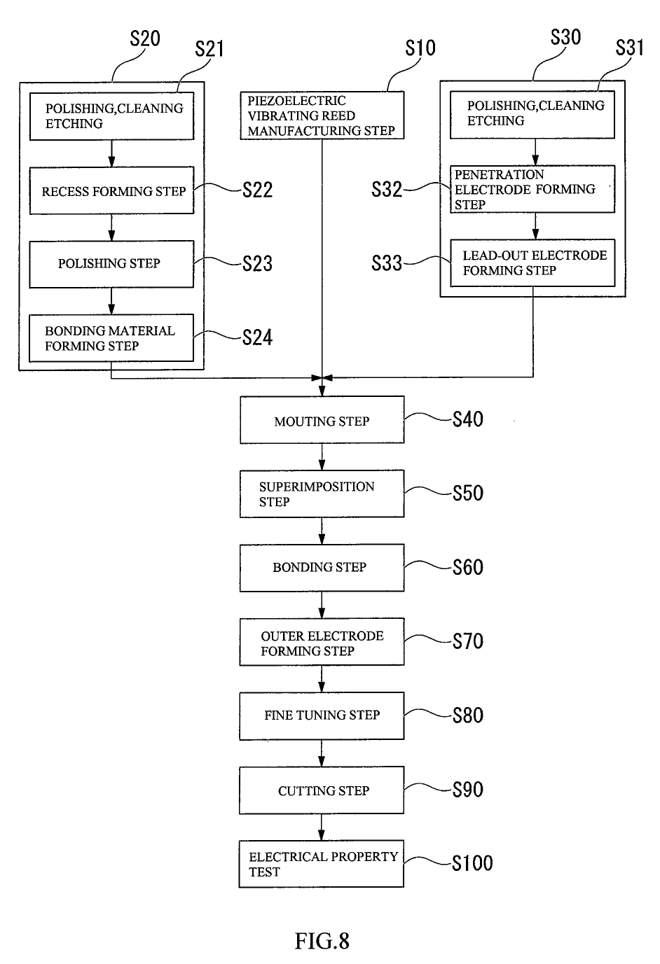

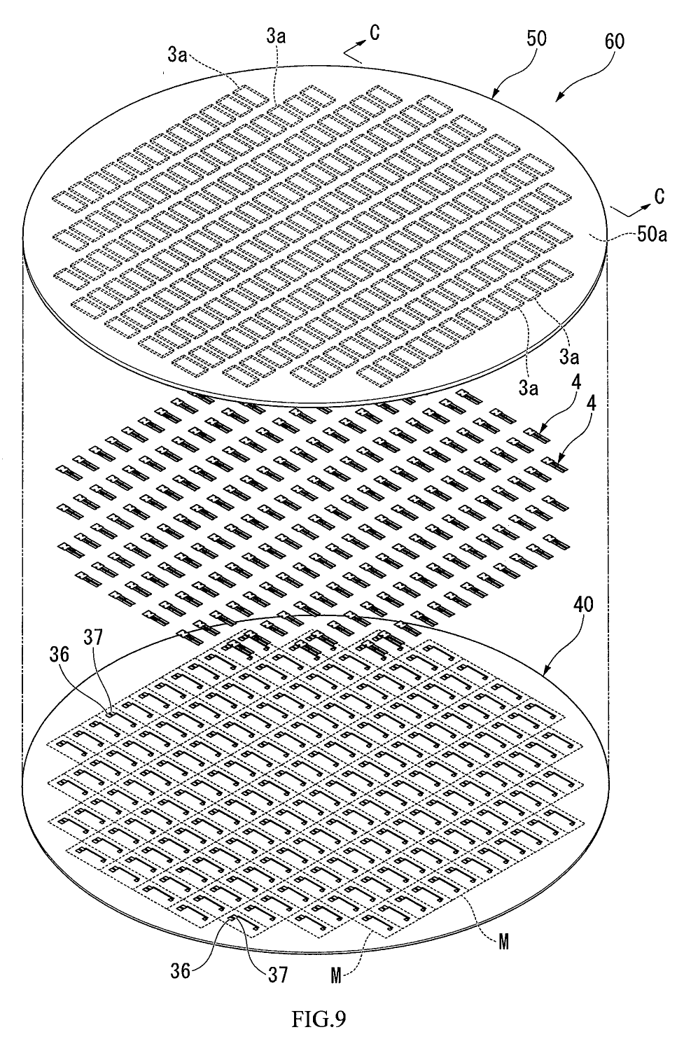

Next, a method for manufacturing the piezoelectric vibrator according to the present embodiment will be described. FIG. 8 is a flowchart of the manufacturing method of a piezoelectric vibrator according to an embodiment of the present invention. FIG. 9 is an exploded perspective view of a wafer assembly. In the following description, a method for manufacturing a plurality of piezoelectric vibrators at a time by enclosing a plurality of piezoelectric vibrating reeds 4 between a base substrate wafer 40 and a lid substrate wafer 50 to form a wafer assembly (glass assembly) 60 and cutting the wafer assembly 60 will be described. The dotted line M shown in the respective figures starting with FIG. 9 is a cutting line along which a cutting step performed later is achieved.

The manufacturing method of the piezoelectric vibrator according to the present embodiment mainly includes a piezoelectric vibrating reed manufacturing step (S10), a lid substrate wafer manufacturing step (S20), a base substrate wafer manufacturing step (S30), and an assembling step (S40 and subsequent steps). Among the steps, the piezoelectric vibrating reed manufacturing step (S10), the lid substrate wafer manufacturing step (S20), and the base substrate wafer manufacturing step (S30) can be performed in parallel. In addition, the manufacturing method of the piezoelectric vibrator according to the present embodiment includes a method for manufacturing a package in which a lid substrate and a base substrate are anodically bonded with a bonding material interposed therebetween. The piezoelectric vibrator manufacturing method mainly includes a bonding material forming step (S24) and a bonding step (S60).

In the piezoelectric vibrating reed manufacturing step (S10), the piezoelectric vibrating reed 4 shown in FIGS. 5 to 7 is manufactured. Specifically, first, a rough quartz crystal Lambert is sliced at a predetermined angle to obtain a wafer having a constant thickness. Subsequently, the wafer is subjected to crude processing by lapping, and an affected layer is removed by etching. Then, the wafer is subjected to mirror processing such as polishing to obtain a wafer having a predetermined thickness. Subsequently, the wafer is subjected to appropriate processing such as washing, and the wafer is patterned so as to have the outer shape of the piezoelectric vibrating reed 4 by a photolithography technique. Moreover, a metal film is formed and patterned on the wafer, thus forming the excitation electrode 15, the extraction electrodes 19 and 20, the mount electrodes 16 and 17, and the weight metal film 21. In this way, a plurality of piezoelectric vibrating reeds 4 can be manufactured. Subsequently, rough tuning of the resonance frequency of the piezoelectric vibrating reed 4 is performed. This rough tuning is achieved by irradiating the rough tuning film 21a of the weight metal film 21 with a laser beam to evaporate in part the rough tuning film 21a, thus changing the weight of the vibrating arms 10 and 11.

In the lid substrate wafer manufacturing step (S20), the lid substrate wafer 50 (see FIG. 9) later serving as the lid substrate 3 is manufactured. In this step, first, a disk-shaped lid substrate wafer 50 made of a soda-lime glass is polished to a predetermined thickness and cleaned, and then, the affected uppermost layer is removed by etching or the like (S21). Subsequently, a plurality of recess portions 3a for cavities is formed on a bonding surface of the lid substrate wafer 50 (see FIG. 9) to be bonded to the base substrate wafer 40 (S22). The recess portions 3a are formed by heat-press molding, etching, or the like. After that, the bonding surface (the frame region 3c) bonded to the base substrate wafer 40 is polished (S23).

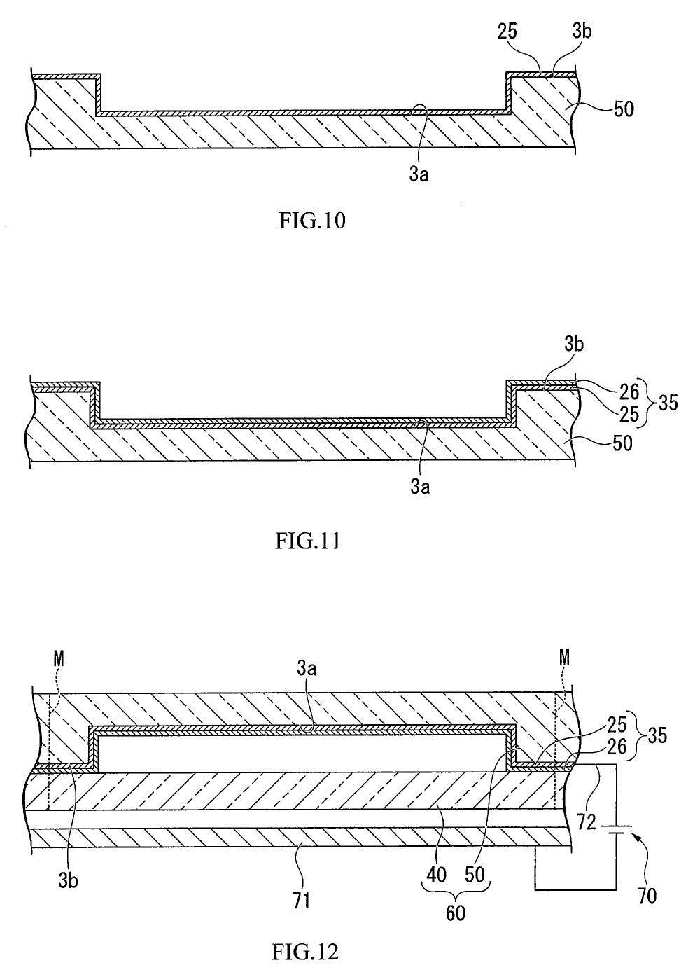

FIGS. 10 and 11 illustrate a bonding material forming step and are cross-sectional views of a lid substrate wafer.

Subsequently, the bonding material 35 is formed on a bonding surface of the lid substrate wafer 50 to be bonded to the base substrate wafer 40 (S24). Specifically, as shown in FIG. 10, first, the ITO film 25 is deposited on the bonding surface of the lid substrate wafer 50 by a sputtering method or the like. In this case, the ITO film 25 is deposited on the entire inner surface of the recess portion 3a in addition to the bonding surface of the lid substrate wafer 50 to be bonded to the base substrate wafer 40 (hereinafter, these regions will be collectively referred to as an inner surface 50a of the lid substrate wafer 50). After that, as shown in FIG. 11, the Si film 26 is formed on the ITO film 25 by a sputtering method, a CVD method, or the like. In this case, the Si film 26 is also deposited on the entire inner surface 50a of the lid substrate wafer 50. In this way, the bonding material 35 in which the ITO film 25 and the Si film 26 are sequentially laminated on the inner surface 50a of the lid substrate 50 is formed.

As described above, by forming the bonding material 35 (the ITO film 25 and the Si film 26) on the entire inner surface 50a of the lid substrate wafer 50, it is not necessary to perform the patterning of the bonding material 35 and it is possible to decrease the manufacturing cost. The bonding material 35 may be patterned after deposition so that it is formed on only the bonding regions of the lid substrate wafer 50 to be bonded to the base substrate wafer 40. Since the polishing step (S23) is performed before the bonding material forming step (S24), the flatness of the surface of the bonding material 35 can be secured, and stable bonding with the base substrate wafer 40 can be achieved.

In the base substrate wafer manufacturing step (S30), the base substrate wafer 40 later serving as the base substrate 2 is manufactured. In this step, first, a disk-shaped base substrate wafer 40 made of a soda-lime glass is polished to a predetermined thickness and cleaned, and then, the affected uppermost layer is removed by etching or the like (S31). Subsequently, a penetration electrode forming step is performed where the pair of penetration electrodes 32 and 33 is formed on the base substrate wafer 40 (S32). The penetration electrodes 32 and 33 are formed by forming the through holes 30 and 31 in the base substrate wafer 40, filling a conductive material such as a silver paste in the through holes 30 and 31, and baking the conductive material. Subsequently, a lead-out electrode forming step is performed where the lead-out electrodes 36 and 37 are formed so as to be electrically connected to the pair of penetration electrodes 32 and 33 (S33).

Meanwhile, forming the bonding material 35 on the surface of the base substrate wafer 40 together with the lead-out electrodes 36 and 37 may be considered. However, in this case, the bonding material 35 is formed after formation of the lead-out electrodes 36 and 37 and the manufacturing time will increase. In addition, in order to prevent diffusion between both members, it is necessary to form the bonding material 35 while masking the lead-out electrodes 36 and 37, and thus the manufacturing process becomes complicated. On the contrary, in the present embodiment, the bonding material 35 is formed on the lid substrate wafer 50, and the lead-out electrodes 36 and 37 are formed on the base substrate wafer 40. Therefore, the formation of the lead-out electrodes 36 and 37 can be performed in parallel with the formation of the bonding material 35, and thus the manufacturing time can be reduced. In addition, since it is not necessary to consider diffusion between both members, it is possible to simplify the manufacturing process.

In a mounting step (S40), a plurality of manufactured piezoelectric vibrating reeds 4 is bonded to the upper surfaces of the lead-out electrodes 36 and 37 of the base substrate wafer 40. Specifically, first, bumps B made of gold or the like are formed on the pair of lead-out electrodes 36 and 37. The base portion 12 of the piezoelectric vibrating reed 4 is placed on the bumps B, and the piezoelectric vibrating reed 4 is pressed against the bumps B while heating the bumps B to a predetermined temperature. In this way, the base portion 12 is mechanically fixed to the bumps B in a state where the vibrating arms 10 and 11 of the piezoelectric vibrating reed 4 are floated from the inner surface of the base substrate wafer 40. In addition, the mount electrodes 16 and 17 are electrically connected to the lead-out electrodes 36 and 37.

In a superimposition step (S50), the lid substrate wafer 50 is superimposed onto the base substrate wafer 40 on which the mounting of the piezoelectric vibrating reed 4 is completed. Specifically, both wafers 40 and 50 are aligned at a correct position using reference marks or the like not shown in the figure as indices. In this way, the piezoelectric vibrating reed 4 mounted on the base substrate wafer 40 is accommodated in the cavity C which is surrounded by the recess portion 3a of the lid substrate wafer 50 and the base substrate wafer 40.

FIG. 12 illustrates a bonding step and is a partially enlarged cross-sectional view taken along the line C-C in FIG. 9.

As shown in FIG. 12, in the bonding step (S60) of the present embodiment, the above-described direct electrode method is used. Specifically, an electrode substrate (negative electrode) 71 made of a conductive material is disposed on the outer surface of the base substrate wafer 40. The electrode substrate 71 is a substrate-like member that is formed approximately in the same shape as the base substrate wafer 40 in a planar view thereof. On the other hand, a terminal (positive electrode) 72 is connected to the ITO film 25 at the outer circumferential end of the lid substrate wafer 50.

Subsequently, the base substrate wafer 40 and the lid substrate wafer 50 are pressed by a jig (not shown) so as to apply pressure to the wafer assembly 60. In this state, the wafer assembly 60 is inserted into an anodic bonding machine for each jig. Subsequently, the inside of the anodic bonding machine is maintained at a predetermined temperature so as to heat the wafer assembly 60. At the same time, a DC power supply 70 is connected to the terminal 72 and the electrode substrate 71, and a voltage is applied between the terminal 72 and the electrode substrate 71 so that the bonding material 35 serves as the positive electrode and the electrode substrate 71 serves as the negative electrode. By doing so, an electrochemical reaction occurs at an interface between the Si film 26 of the bonding film 35 and the base substrate wafer 40, whereby they are closely adhered tightly and anodically bonded.

As a method for anodically bonding the two substrate wafers 40 and 50, there is known a method (a so-called counter electrode method) in which an auxiliary bonding material serving as a positive electrode is disposed on the outer surface of the lid substrate wafer 50 and an electrode substrate serving as a negative electrode is disposed on the outer surface of the base substrate wafer 40. When the counter electrode method is used, a material which can be anodically bonded to the lid substrate wafer is used as the auxiliary bonding material, and the bonding material 35 (the Si film 26) and the base substrate wafer 40 are bonded in conjunction with the anodic bonding reaction between the auxiliary bonding material and the lid substrate wafer 50. Therefore, in the counter electrode method, it is necessary to perform a step of removing the auxiliary bonding material bonded to the lid substrate wafer 50 after the bonding step.

In contrast, according to the present embodiment, the ITO film 25 is used as the positive electrode, the electrode substrate 71 serving as the negative electrode is disposed on the outer surface of the base substrate wafer 40, and a voltage is applied between the ITO film 25 and the base substrate wafer 40. Therefore, it is possible to decrease the number of operation steps and to improve the manufacturing efficiency compared to the counter electrode method described above.

In an outer electrode forming step (S70), the outer electrodes 38 and 39 are formed on the rear surface of the base substrate wafer 40.

In a fine tuning step (S80), the frequencies of the individual piezoelectric vibrators 1 are tuned finely. Specifically, first, a predetermined voltage is continuously applied from the outer electrodes 38 and 39 to vibrate the piezoelectric vibrating reed 4, and the vibration frequency is measured. In this state, a laser beam is irradiated onto the base substrate wafer 40 from the outer side to evaporate the fine tuning film 21b of the weight metal film 21. By doing so, since the weight on the tip end sides of the pair of vibrating arms 10 and 11 decreases, the frequency of the piezoelectric vibrating reed 4 increases. In this way, the frequency of the piezoelectric vibrator 1 is tuned finely so as to fall within the range of the nominal frequency.

In a cutting step (S90), the bonded wafer assembly 60 is cut along the cutting line M. Specifically, first, a UV tape is attached on the surface of the base substrate wafer 40 of the wafer assembly 60. Subsequently, a laser beam is irradiated along the cutting line M from the side of the lid substrate wafer 50 (scribing). Subsequently, the wafer assembly 60 is divided and cut along the cutting line M by a cutting blade pressing against the surface of the UV tape (breaking). After that, the UV tape is separated by irradiation of UV light. In this way, it is possible to divide the wafer assembly 60 into a plurality of piezoelectric vibrators. The wafer assembly 60 may be cut by other methods such as dicing.

In an electrical property test step (S100), the resonance frequency, resonance resistance value, drive level properties (the excitation power dependence of the resonance frequency and the resonance resistance value), and the like of the piezoelectric vibrator 1 are measured and checked. Moreover, the insulation resistance value properties and the like are checked as well. Finally, an external appearance test of the piezoelectric vibrator 1 is conducted to check the dimensions, the quality, and the like.

In this way, the piezoelectric vibrator 1 is manufactured.

As described above, in the bonding material forming step (S24), the bonding material 35 is formed by sequentially forming the ITO film 25 and the Si film 26 on the inner surface 50a of the lid substrate wafer 50.

According to this configuration, by forming the ITO film 25 which is a conductive film on the inner surface 50a of the lid substrate wafer 50, it is possible to decrease the sheet resistance of the bonding material 35 compared to the case of forming the bonding material 35 only of the Si film 26 having a large sheet resistance. In this way, even when the thickness of the Si film 26 is decreased, it is possible to apply a uniform voltage to the entire surface of the bonding material 35. In this case, since the anodic bonding can be achieved with a relatively low voltage, it is possible to decrease energy consumption and the production cost. Moreover, since the thickness of the Si film 26 can be decreased, it is possible to decrease the deposition time of the Si film 26 and to improve the manufacturing efficiency. In the related art, when the bonding material made only of the Si film was formed to a thickness of 1500 Å, the sheet resistance was very high as about 500 k Ω/sq. In contrast, in the bonding material 35 in which the thickness of the ITO film 25 is about 1000 Å to 1500 Å, and the thickness of the Si film 26 is about 1500 Å as described above, the sheet resistance can be decreased to about 20 Ω/sq.

Moreover, in the present embodiment, since the potential is uniform within the entire surface of the bonding material 35, even when the Si film 26 having a large sheet resistance is used as the material for the bonding material 26, the two glass substrates 40 and 50 can be tightly anodically bonded over the entire region of the bonding surface. As a result, it is possible to provide the package 9 having excellent airtightness. Moreover, since the piezoelectric vibrating reed 4 is sealed in the package 9, it is possible to improve the vacuum sealing reliability of the piezoelectric vibrating reed 4. In this way, since a series resonance resistance value (R1) of the piezoelectric vibrator 1 is maintained at a low state, it is possible to vibrate the piezoelectric vibrating reed 4 with a low power. Thus, it is possible to manufacture the piezoelectric vibrator 1 having excellent energy efficiency.

Furthermore, in the present embodiment, even when the terminal 72 is connected to the outer circumferential end of the base substrate wafer 40, it is possible to apply a uniform voltage to the entire surface of the bonding material 35. That is, it is possible to easily form the wafer assembly 60 in which the entire regions of the bonding surfaces of the two substrate wafers 40 and 50 are tightly anodically bonded without the necessity of connecting the terminal 72 at plurality of positions and considering the connection positions of the terminal 72 in order to apply a uniform voltage to the entire surface of the bonding material 35.

Furthermore, since the ITO film 25 and the Si film 26 have resistance to corrosion, even when the bonding material 35 used for the anodic bonding is exposed to the outside, the bonding material 35 is not corroded. Therefore, it is not necessary to perform coating processing after the anodic bonding unlike the case of using Al for the bonding material, for example. In this way, it is possible to improve the manufacturing efficiency.

### Oscillator

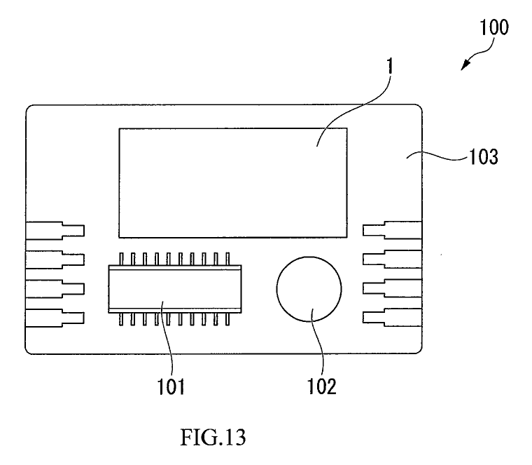

Next, an oscillator according to another embodiment of the invention will be described with reference to FIG. 13.

In an oscillator 100 according to the present embodiment, the piezoelectric vibrator 1 is used as an oscillating piece electrically connected to an integrated circuit 101, as shown in FIG. 13. The oscillator 100 includes a substrate 103 on which an electronic component 102, such as a capacitor, is mounted. The integrated circuit 101 for an oscillator is mounted on the substrate 103, and the piezoelectric vibrator 1 is mounted near the integrated circuit 101. The electronic component 102, the integrated circuit 101, and the piezoelectric vibrator 1 are electrically connected to each other by a wiring pattern (not shown). In addition, each of the constituent components is molded with a resin (not shown).

In the oscillator 100 configured as described above, when a voltage is applied to the piezoelectric vibrator 1, the piezoelectric vibrating reed 4 in the piezoelectric vibrator 1 vibrates. This vibration is converted into an electrical signal due to the piezoelectric property of the piezoelectric vibrating reed 4 and is then input to the integrated circuit 101 as the electrical signal. The input electrical signal is subjected to various kinds of processing by the integrated circuit 101 and is then output as a frequency signal. In this way, the piezoelectric vibrator 1 functions as an oscillating piece.

Moreover, by selectively setting the configuration of the integrated circuit 101, for example, an RTC (real time clock) module, according to the demands, it is possible to add a function of controlling the operation date or time of the corresponding device or an external device or of providing the time or calendar in addition to a single functional oscillator for a clock.

As described above, since the oscillator 100 according to the present embodiment includes the high-quality piezoelectric vibrator 1 in which the base substrate 2 and the lid substrate 3 are securely anodically bonded, and reliable airtightness of the cavity C is secured, and which has improved yield, it is possible to achieve an improvement in the operational reliability and the quality of the oscillator 100 itself which provides stable conductivity. In addition to this, it is possible to obtain a highly accurate frequency signal which is stable over a long period of time.

### Electronic Device

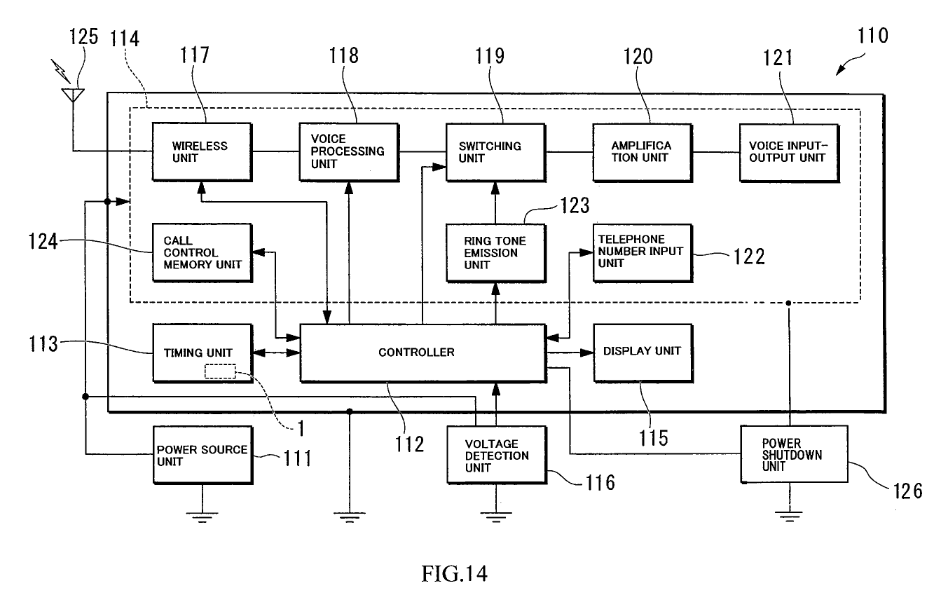

Next, an electronic device according to another embodiment of the invention will be described with reference to FIG. 14. In addition, a portable information device 110 including the piezoelectric vibrator 1 will be described as an example of an electronic device.

The portable information device 110 according to the present embodiment is represented by a mobile phone, for example, and has been developed and improved from a wristwatch in the related art. The portable information device 110 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built in an inner portion of the band. However, the portable information device 110 is very small and light compared with a mobile phone in the related art.

Next, the configuration of the portable information device 110 according to the present embodiment will be described. As shown in FIG. 14, the portable information device 110 includes the piezoelectric vibrator 1 and a power supply section 111 for supplying power. The power supply section 111 is formed of a lithium secondary battery, for example. A control section 112 which performs various kinds of control, a clock section 113 which performs counting of time and the like, a communication section 114 which performs communication with the outside, a display section 115 which displays various kinds of information, and a voltage detecting section 116 which detects the voltage of each functional section are connected in parallel to the power supply section 111. In addition, the power supply section 111 supplies power to each functional section.

The control section 112 controls an operation of the entire system. For example, the control section 112 controls each functional section to transmit and receive the audio data or to measure or display a current time. In addition, the control section 112 includes a ROM in which a program is written in advance, a CPU which reads and executes a program written in the ROM, a RAM used as a work area of the CPU, and the like.

The clock section 113 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed 4 vibrates, and this vibration is converted into an electrical signal due to the piezoelectric property of quartz crystal and is then input to the oscillation circuit as the electrical signal. The output of the oscillation circuit is binarized to be counted by the register circuit and the counter circuit. Then, a signal is transmitted to or received from the control section 112 through the interface circuit, and current time, current date, calendar information, and the like are displayed on the display section 115.

The communication section 114 has the same function as a mobile phone in the related art, and includes a wireless section 117, an audio processing section 118, a switching section 119, an amplifier section 120, an audio input/output section 121, a telephone number input section 122, a ring tone generating section 123, and a call control memory section 124.

The wireless section 117 transmits/receives various kinds of data, such as audio data, to/from the base station through an antenna 125. The audio processing section 118 encodes and decodes an audio signal input from the wireless section 117 or the amplifier section 120. The amplifier section 120 amplifies a signal input from the audio processing section 118 or the audio input/output section 121 up to a predetermined level. The audio input/output section 121 is formed by a speaker, a microphone, and the like, and amplifies a ring tone or incoming sound louder or collects the sound.

In addition, the ring tone generating section 123 generates a ring tone in response to a call from the base station. The switching section 119 switches the amplifier section 120, which is connected to the audio processing section 118, to the ring tone generating section 123 only when a call arrives, so that the ring tone generated in the ring tone generating section 123 is output to the audio input/output section 121 through the amplifier section 120.

In addition, the call control memory section 124 stores a program related to incoming and outgoing call control for communications. Moreover, the telephone number input section 122 includes, for example, numeric keys from 0 to 9 and other keys. The user inputs a telephone number of a communication destination by pressing these numeric keys and the like.

The voltage detecting section 116 detects a voltage drop when a voltage, which is applied from the power supply section 111 to each functional section, such as the control section 112, drops below the predetermined value, and notifies the control section 112 of the detection. In this case, the predetermined voltage value is a value which is set beforehand as the lowest voltage necessary to operate the communication section 114 stably. For example, it is about 3 V. When the voltage drop is notified from the voltage detecting section 116, the control section 112 disables the operation of the wireless section 117, the audio processing section 118, the switching section 119, and the ring tone generating section 123. In particular, the operation of the wireless section 117 that consumes a large amount of power should be necessarily stopped. In addition, a message informing that the communication section 114 is not available due to insufficient battery power is displayed on the display section 115.

That is, it is possible to disable the operation of the communication section 114 and display the notice on the display section 115 by the voltage detecting section 116 and the control section 112. This message may be a character message. Or as a more intuitive indication, a cross mark (X) may be displayed on a telephone icon displayed at the top of the display screen of the display section 115.

In addition, the function of the communication section 114 can be more reliably stopped by providing a power shutdown section 126 capable of selectively shutting down the power of a section related to the function of the communication section 114.

As described above, since the portable information device 110 according to the present embodiment includes the high quality piezoelectric vibrator 1 in which the base substrate 2 and the lid substrate 3 are securely anodically bonded, and reliable airtightness of the cavity C is secured, and which has improved yield, it is possible to achieve an improvement in the operational reliability and the quality of the portable information device 110 itself which provides stable conductivity. In addition to this, it is possible to display highly accurate clock information which is stable over a long period of time.

### Radio-Controlled Timepiece

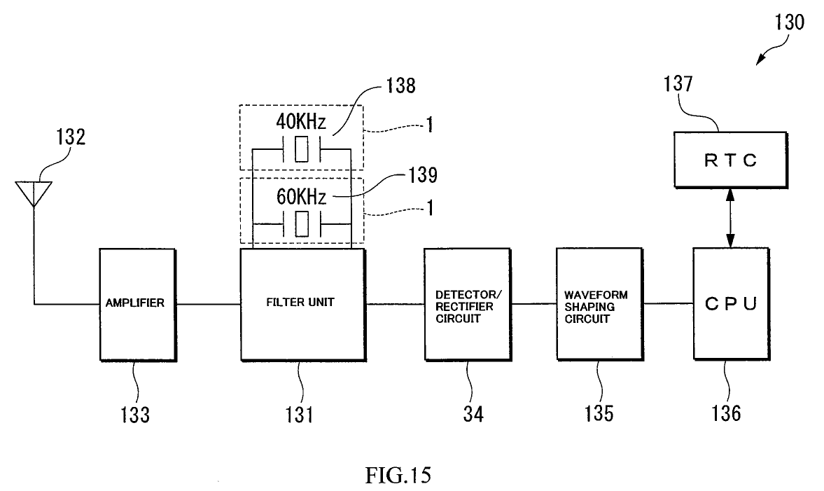

Next, a radio-controlled timepiece according to still another embodiment of the invention will be described with reference to FIG. 15.

As shown in FIG. 15, a radio-controlled timepiece 130 according to the present embodiment includes the piezoelectric vibrators 1 electrically connected to a filter section 131. The radio-controlled timepiece 130 is a clock with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionosphere and the land surface, and therefore has a propagation range wide enough to cover the entire area of Japan through the two transmission centers.

Hereinafter, the functional configuration of the radio-controlled timepiece 130 will be described in detail.

An antenna 132 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 133 and is then filtered and synchronized by the filter section 131 having the plurality of piezoelectric vibrators 1. In the present embodiment, the piezoelectric vibrators 1 include crystal vibrator sections 138 and 139 having resonance frequencies of 40 kHz and 60 kHz, respectively, which are the same frequencies as the carrier frequency.

In addition, the filtered signal with a predetermined frequency is detected and demodulated by a detection and rectification circuit 134. Then, the time code is extracted by a waveform shaping circuit 135 and counted by the CPU 136. The CPU 136 reads the information including the current year, the total number of days, the day of the week, the time, and the like. The read information is reflected on an RTC 137, and the correct time information is displayed.

Because the carrier wave is 40 kHz or 60 kHz, a vibrator having the tuning fork structure described above is suitable for the crystal vibrator sections 138 and 139.

Moreover, although the above explanation has been given for the case of Japan, the frequency of a long standard wave is different in other countries. For example, a standard wave of 77.5 kHz is used in Germany. Therefore, when the radio-controlled timepiece 130 which is also operable in other countries is assembled in a portable device, the piezoelectric vibrator 1 corresponding to frequencies different from the frequencies used in Japan is necessary.

As described above, since the radio-controlled timepiece 130 according to the present embodiment includes the piezoelectric vibrator 1 in which the base substrate 2 and the lid substrate 3 are securely anodically bonded, and reliable airtightness of the cavity C is secured, and which has improved yield, it is possible to achieve an improvement in the operational reliability and the quality of the radio-controlled timepiece 130 itself which provides stable conductivity. In addition to this, it is possible to count the time highly accurately and stably over a long period of time.

It should be noted that the technical scope of the present invention is not limited to the embodiments above, and the present invention can be modified in various ways without departing from the spirit of the present invention. That is, specific materials and layer structures exemplified in the embodiments are only examples and can be appropriately changed.

In the above-described embodiment, although the bonding material is formed on the inner surface 50a of the lid substrate wafer 50, contrary to this, the bonding material may be formed on the inner surface of the base substrate wafer.

Moreover, in the above-described embodiment, although the anodic bonding is performed using the direct electrode method, the present invention is not limited to this, and the anodic bonding may be performed using a counter electrode method.

In the above-described embodiment, although the piezoelectric vibrator is manufactured by sealing the piezoelectric vibrating reed on the inner side of the package while using the package manufacturing method according to the present invention, devices other than the piezoelectric vibrator may be manufactured by sealing an electronic component other than the piezoelectric vibrating reed on the inner side of the package.

What is claimed is:

1. A method for producing piezoelectric vibrators, comprising:
(a) defining a plurality of first substrates on a first wafer and a plurality of second substrates on a second wafer;
(b) forming a bonding layer on a main surface of a respective at least some of the second substrates, wherein the bonding layer comprises at least two sub-layers comprising a silicon sub-layer and a conductive sub-layer;
(c) layering the first and second wafers such that at least some of the first substrates substantially coincide respectively with at least some of the corresponding second substrates, wherein a piezoelectric vibrating reed is secured in a respective at least some of the coinciding first and second substrate pairs;
(d) anodically bonding a respective at least some of the coinciding first and second substrate pairs which each include the bonding layer therebetween; and
(e) cutting off a respective at least some of the anodically bonded first and second substrate pairs from the first and second wafers.

2. The method according to claim 1, wherein forming a bonding layer comprises forming the conductive sub-layer and forming the silicon sub-layer over the conductive sub-layer.

3. The method according to claim 1, wherein the silicon sub-layer has a thickness of about 1500 Å.

4. The method according to claim 1, wherein the conductive sub-layer comprises an Indium Tin Oxide layer comprising indium oxide added with tin oxide at 5 to 10 wt %.

5. The method according to claim 1, wherein the conductive sub-layer has a thickness of about 1000 Å to about 1500 Å.

6. The method according to claim 1, wherein the bonding layer has a sheet resistance of about 20 Ω/sq.

7. The method according to claim 1, wherein forming a bonding layer on a main surface comprises forming the bonding layer on the entirety of the main surface.

8. The method according to claim 1, wherein anodically bonding a respective at least some of the coinciding first and second substrate pairs comprises applying a voltage across the bonding layer and an electrode plate being in contact with the first wafer.

9. The method according to claim 1, wherein the main surface is a recess.

10. A piezoelectric vibrator comprising:
a hermetically closed casing comprising anodically bonded first and second substrates with a cavity inside;
a bonding layer placed between the first and second substrates and used to anodically bond the substrates, wherein the bonding layer comprises at least two sub-layers comprising a silicon sub-layer and a conductive sub-layer; and
a piezoelectric vibrating strip secured inside the cavity.

11. The piezoelectric vibrator according to claim 10, wherein the silicon sub-layer is in direct contact with the first substrate and in contact with the second substrate via the conductive sub-layer.

12. The piezoelectric vibrator according to claim 10, wherein the silicon sub-layer has a thickness of about 1500 Å.

13. The piezoelectric vibrator according to claim 10, wherein the conductive sub-layer comprises an Indium Tin Oxide layer comprising indium oxide added with tin oxide at 5 to 10 wt %.

14. The piezoelectric vibrator according to claim 10, wherein the conductive sub-layer has a thickness of about 1000 Å to about 1500 Å.

15. The piezoelectric vibrator according to claim 10, wherein the bonding layer has a sheet resistance of about 20 Ω/sq.

16. The piezoelectric vibrator according to claim 10, wherein the second substrate has a recess to form the cavity.

17. The piezoelectric vibrator d according to claim 16, wherein the bonding layer covers the entirety of a main surface of the second substrate in which the recess in formed.

18. An oscillator comprising the piezoelectric vibrator defined in claim 10.

19. An electronic device comprising the piezoelectric vibrator defined in claim 10 which is electrically connected to a clock section of the electronic device.

20. A radio-controlled timepiece comprising the piezoelectric vibrator defined in claim 10 which is electrically connected to a filter section of the radio-controlled timepiece.
